(19) United States
(12) Patent Application Publication
(10) Pub. No.: US 2010/0320457 A1
(43) Pub. Date: Dec. 23, 2010

(54) ETCHING SOLUTION COMPOSITION

(76) Inventors: Masahito Matsubara, Chiba (JP); Kazuyoshi Inoue, Chiba (JP); Koki Yano, Chiba (JP); Yuki Igarashi, Tokyo (JP)

Correspondence Address: WOLF GREENFIELD & SACKS, P.C., 600 ATLANTIC AVENUE, BOSTON, MA, 02210-2206, US

(21) Appl. No.: 12/744,380

(22) PCT Filed: Nov. 21, 2008
(86) PCT No.: PCT/JP2008/071194

§ 371 Date: Sep. 3, 2010

(30) Foreign Application Priority Data
Nov. 22, 2007 (JP) 2007-303428

(51) Int. Cl. H01L 29/22; H01L 21/465; H01L 21/336; C09K 13/00

(52) U.S. Cl. 257/43; 438/745; 438/104; 252/79.1; 438/151; 257/E21.409; 257/E29.095; 257/E21.485

(57) ABSTRACT

Provided is an etching solution composition for selectively etching a metal film, which is composed of Al, Al alloy or the like and is arranged on an amorphous oxide film, from a laminated film including the metal film and an amorphous oxide film of various types. The etching solution composition is used for selectively etching the metal film from the laminated film which includes the amorphous oxide film and the metal film composed of Al, Al alloy, Cu, Cu alloy, Ag or Ag alloy, and is composed of an aqueous solution containing an alkali.

### TECHNICAL FIELD

The present invention relates to an etching solution composition for selectively etching a metal film in a laminated film comprising an amorphous oxide film and said metal film that is composed of Al, Al alloy, etc. The present invention further relates to an etched laminated film using said etching solution composition, a liquid crystal display panel and a liquid crystal display device comprising said laminated film, and a method for manufacturing the same. The present invention also relates to an etching method and a patterning method used for the production of semiconductor elements, integrated circuits, microelectronic components such as electrodes, and a method for manufacturing thin-film transistors, using such etching solution composition.

### BACKGROUND ART

In manufacturing thin-film transistor display panels, as a method to increase the viewing angle of display panels and the response speed of moving images, systems such as fringe field switching (FFS) mode and in-plane switching (IPS) mode are used, and a selective etching step of a metal film on a transparent electrode is required during the process of manufacturing these systems.

In recent years, under the progress of miniaturization, weight-saving and low-power-consumption technology of electronic devices, oxide semiconductors (IGZO) composed of indium (In), gallium (Ga) and zinc (Zn) have been attracting attention in the field of display. Since amorphous oxide semiconductor films of IGZO can be formed on a resin film at low temperature, their future application to light-weight portable electronic items and others is being examined.

As a thin metal film on a transparent conductive film, Al or Al alloys and Mo or Mo alloys are generally used; as a transparent conductive film, indium thin oxide (ITO), indium zinc oxide (IZO), etc. are generally used.

Conventionally, etching solutions that have been used for Al, Al alloy, Mo, Mo alloy, IZO, ITO, etc. are classified into acidic etching solution, neutral etching solution and alkaline etching solution. Al is an amphoteric compound, dissolves in both acidic and alkaline etching solutions, and also dissolves in neutral etching solutions of oxidizing nature. Mo is not an amphoteric compound, but dissolves in acidic etching solutions containing an oxidizing agent, alkaline etching solutions containing an oxidizing agent, and neutral etching solutions containing an oxidizing agent. ITO has different crystallinity depending on the process of its manufacture; when it has high crystallinity, it only dissolves in limited types of strong acids such as aqua regia, etc. However, generally-used ITO is an amorphous ITO that can be formed by sputtering at room temperature, which dissolves in both acidic and alkaline etching solutions. IZO is only in the form of amorphous IZO, which dissolves in both acidic and alkaline etching solutions. Zinc oxide is an amphoteric compound, which dissolves in both acidic and alkaline etching solutions. There are a number of reports regarding acidic etching solution, and obviously acidic etching solutions can dissolve all of Al, Al alloy, Mo, Mo alloy, ITO, IZO and zinc oxide; there is no example in which a metal film over a transparent conductive film is highly-selectively etched with an acidic etching solution.

Specifically, the following technologies are disclosed regarding transparent conductive layers and metals. ITO films have different crystallinity depending on their manufacturing process, and are known to form α(amorphous)-ITO by sputtering at room temperature. IZO also becomes amorphous when formed by sputtering at 300° C. or lower. These amorphous films dissolve in weakly-acidic etching solutions such as oxalic acid, and a mixed acid consisting of phosphoric acid, acetic acid and nitric acid (Patent Literature 1). In particular, with respect to α-ITO films, a method for etching a transparent conductive layer using an etching solution comprising one or more compounds selected from the group consisting of polysulfonic acid and polyoxyethylene-polyoxypropyrere block copolymer has been proposed (Patent Literature 2).

As an etching solution for 3-laminated layers consisting of patterned resist/Mo/Al/Mo/IZO substrate, etc., a method wherein the layers were simultaneously etched using an aqueous solution comprising 30-45 wt % of phosphoric acid, 15-35 wt % of nitric acid, an organic acid and a cation component has been reported (Patent Literature 1). When a laminated film of Mo and Al is etched using a mixed acid consisting of phosphoric acid, acetic acid and nitric acid, a technology in which mixed acids with different compositions are used for Al and Mo has been reported, because etch rate differs between Al and MO (Patent Literature 3). Furthermore, there is a report on a technology to improve etching of a laminated film of ITO and Al, by means of optimizing the blending ratio of the Al alloy to lower solubility to an oxalic acid solution (Patent Literature 4). However, no etching method to etch a metal on a transparent conductive film using an acidic etching solution has yet been proposed.

Accordingly, crystallized ITO (p-ITO) is used in a manufacturing process of FFS-LCD. However, because etching characteristic of p-ITO is extremely low, ITO residues tend to be generated after etching, and this would cause short-circuiting even if a metal thin film is formed thereon. Therefore, a new manufacturing process of FFS-LCD has been proposed, with which no short-circuiting occurs even under the presence of residues (Patent Literature 5). However, since the step of partial patterning of gate insulating films must be added to this method, the manufacturing cost increases due to the necessity of changing masks and others.

Meanwhile, while a metal film on a transparent conductive film also dissolves in alkaline solutions, in general, alkaline solutions are rarely used for etching the meal film on a transparent conductive film. The first reason for this is the reduction of ITO due to oxidation of aluminum when the laminated film consisting of aluminum and ITO is in contact with alkali. In order to avoid the effect of alkaline solution as an exfoliation liquid of positive photoresists, a technology wherein a nitrate salt as an oxidizing agent is added to the alkaline aqueous solution has been reported (Patent Literature 6). As the second reason, each of the metal film and the transparent conductive film is considered to be dissolved in alkali. For example, there is a report on the technology wherein Al is dissolved by ammonium hydroxide (Patent Literature 7), and Mo is reported to be etched by an alkaline aqueous solution containing an oxidizing agent (Patent Literature 8).

Zinc oxide is an amphoteric compound, and is known to dissolve in ammonia water (Patent Literature 9). Furthermore, IZO and ITO are reported to be easily penetrated by an alkanolamine solution with pH of 13.5 or more (Patent Literature 10). Thus, regarding both acidic and alkaline etching solutions, conventionally, no solutions that can selectively etch a metal in a laminated film consisting of a transparent conductive film and the metal film have been known.

On the other hand, patterning of a metal film over an amorphous oxide semiconductor film composed of fabricated In, Ga and Zn has conventionally been conducted by lift-off method (Non-Patent Literature 1). However, since a photoresist has low heat resistance, when a process of high-temperature treatment is required in the lift-off method, the photoresist may be deformed by melting. In addition, in the process of removing photoresist, the pattern edge of the vapor-deposited film may be curled up.

Generally, in etching a metal thin film on an amorphous oxide semiconductor film, a mixed acid of phosphoric acid/acetic acid/nitric acid, as well as a ceric ammonium nitrate solution are used. However, when such an acidic etching solution is used, upon etching a metal film over the amorphous oxide semiconductor film of an oxide (IGZO, IZO, ITZO) composed of at least one of Ga, Zn and Sn, as well as In, said co-existing amorphous oxide semiconductor film (that is of an oxide (IGZO, IZO, ITZO) composed of at least one of Ga, Zn and Sn, as well as In) could be etched with the same etch rate.

### Patent Literature 1: JP A 2005-277402

### Patent Literature 2: JP B 3345408

### Patent Literature 3: JP A 2000-31111

### Patent Literature 4: JP A 2006-210033

### Patent Literature 5: JP A 2002-90781

### Patent Literature 6: JP B 2875553

### Patent Literature 7: JP B 2599485

### Patent Literature 8: JP A 10-307303

### Patent Literature 9: JP A 10-229212

### Patent Literature 10: JP B 3611618

### Patent Literature 11: JP A 2005-258115

### Non-Patent Literature 1: K. Nomura et al., Nature, Vol. 432, 25 Nov. 2004, pp. 488-492

### Non-Patent Literature 2: Applied Physics Letters, 11 Sep. 2006, Vol. 89, No. 11, pp. 112123-1-112123-3.

### DISCLOSURE OF INVENTION

### Problems to be Solved by the Invention

Accordingly, an object of the present invention is to provide an etching solution composition for selectively etching a metal film on an amorphous oxide film in a laminated film comprising said metal film composed of Al, Al alloy, etc. and various types of the amorphous oxide film.

### Means of Solving the Problems

The inventors of the present invention have conducted examinations to solve the above problem, and have found that in a certain alkaline etching solution composition, a high etching selectivity can be obtained between a metal film composed of Al, Al ally, etc. and an amorphous oxide film composed of IZO, etc.

Using a patterning method and a manufacturing process of thin-film transistors utilizing such etching method, it is possible to suppress variations in element characteristics, and to increase stability and uniformity of the element characteristics.

Namely, the present invention relates to an etching solution composition for selectively etching a metal film from a laminated film comprising an amorphous oxide film and said metal film that is composed of at least one selected from the group consisting of Al, Al alloy, Cu, Cu alloy, Ag and Ag alloy, wherein the composition consists of an aqueous solution containing an alkali.

In addition, the present invention relates to the above etching solution composition, wherein the laminated film further comprises a metal film composed of at least one selected from the group consisting of Mo, Mo alloy, Ti and Ti alloy, and said metal film is simultaneously etched.

Furthermore, the present invention relates to the above etching solution composition, wherein the alkali is ammonia.

In addition, the present invention relates to the above etching solution composition, further comprising an oxidizing agent.

Furthermore, the present invention relates to the above etching solution composition, wherein the oxidizing agent is hydrogen peroxide.

In addition, the present invention relates to the above etching solution composition, wherein the amorphous oxide film is a transparent conductive film or an amorphous oxide semiconductor film, said transparent conductive film being a transparent conductive film comprising a-ITO, IZO, zinc oxide or tin oxide, and said amorphous oxide semiconductor film being an amorphous oxide semiconductor film comprising at least one of gallium, zinc and tin, and indium.

Furthermore, the present invention relates to the above etching solution composition, wherein the concentration of ammonia in the etching solution composition is 0.01-25 wt %.

In addition, the present invention relates to the above etching solution composition, wherein the concentration of hydrogen peroxide in the etching solution composition is 0.01-20 wt %.

Furthermore, the present invention relates to the above etching solution composition, wherein the amorphous oxide film is an amorphous oxide semiconductor film comprising at least one of gallium, zinc and tin, and indium, and the concentration of ammonia in the etching solution composition is 0.01-5 wt %.

In addition, the present invention relates to the above etching solution composition, wherein the amorphous oxide film is an amorphous oxide semiconductor film comprising at least one of gallium, zinc and tin, and indium, and the concentration of hydrogen peroxide in the etching solution composition is 0.01-10 wt %.

Furthermore, the present invention relates to the above etching solution composition, which is used for manufacturing a liquid crystal display panel.

In addition, the present invention relates to the above etching solution composition, which is used for manufacturing a liquid crystal display panel of FFS or IPS mode, or a semi-transmissive/semi-reflective liquid crystal display panel.

Furthermore, the present invention relates to a laminated film comprising an amorphous oxide film and a metal film composed of at least one selected from the group consisting of Al, Al alloy, Cu, Cu alloy, Ag and Ag alloy, wherein said metal film is selectively etched using the above etching solution composition.

In addition, the present invention relates to a liquid crystal display panel having the above laminated film.

Furthermore, the present invention relates to a liquid crystal display device having the above liquid crystal display panel.

In addition, the present invention relates to an etching method for a laminated film comprising an amorphous oxide film and a metal film composed of at least one selected from the group consisting of Al, Al alloy, Cu, Cu alloy, Ag and Ag alloy, characterized in that said metal film is selectively etched using the above etching solution composition.

Furthermore, the present invention relates to the above etching method, wherein the laminated film further comprises a metal film composed of at least one selected from the group consisting of Mo, Mo alloy, Ti and Ti alloy, and this metal film is simultaneously etched.

In addition, the present invention relates to a patterning method of a metal film comprising at least one layer selected from the group consisting Al, Al alloy, Cu, Cu alloy, Ag and Ag alloy disposed on an amorphous oxide film, characterized in that the method comprises a step of forming the amorphous oxide film, a step of forming the metal film over the amorphous oxide film, and an etching step of selectively etching the metal film on the amorphous oxide film using the above etching solution composition.

Furthermore, the present invention relates to a process for manufacturing a liquid crystal display panel, comprising an etching step using an etching solution composition.

In addition, the present invention relates to a process for manufacturing a thin-film transistor comprising a step of forming source and drain electrodes, a gate electrode, a gate insulating layer and a semiconductor layer, characterized in that said step of forming the semiconductor layer comprises:

a step of forming an amorphous oxide film,
a step of forming a metal film that comprises at least one selected from the group consisting of Al, Al alloy, Cu, Cu alloy, Ag and Ag alloy over the amorphous oxide film, and
an etching step of selectively etching the metal film on the amorphous oxide film using the above etching solution composition.

### ADVANTAGEOUS EFFECTS OF INVENTION

According to the present invention, by using the alkaline etching solution composition such as ammonia water, a high selectivity between amorphous oxide films and metal films such as Al, Al alloy, etc. can be obtained, which has been impossible by conventional acidic etching solutions such as phosphoric acid, nitric acid and acetic acid which are general etching solutions for Al or Al alloys and Mo or Mo alloys. The etching solution composition of the present invention can be used for laminated films comprising any amorphous oxide films; it is particularly effective for laminated films comprising an amorphous transparent conductive film that would be etched by conventional etching solution compositions.

### DESCRIPTION OF EMBODIMENTS

The etching solution composition of the present invention is an etching solution composition for etching a laminated film comprising an amorphous oxide film and a metal film (first metal film) composed of Al, Al alloy, Cu, Cu alloy, Ag, Ag alloy, etc. wherein the composition is used to selectively etch the first metal film. The first metal film may be a single film, or a laminated film of two or more types of films. In particular, the inventive etching solution composition can be suitably used for Al films or Al alloy films. Examples of Al alloys include AlNd, AlNi, AlCr, AlFe, AlTi, AlCe, etc. Examples of Cu alloys include CuMo, CuZr, CuMn, CuAu, CuMg, CuAl, CuSi, CuNi, CuTi, CuCo, etc. Examples of Ag alloys include AgMo, AgZr, AgSi, AgGe, AgCu, AgSn, AgBi, AgPd, AgNd, AgPdCu, etc. Furthermore, the laminated film may comprise a second metal film such as Mo and Mo alloys (MoW, MoN, MoNb, MoAg, MoTi, MoZr, MoV, MoCr, etc.) and Ti and Ti alloys (TiN, TiV, TiW, TiMo, etc.) in order to prevent oxidation of Al metals; the second metal film may simultaneously be etched with the above first metal film. In particular, Mo films and MoW films may be preferably used. The second metal film may be a single film, or a laminated film of two or more types of films. It may also be provided directly over an amorphous oxide film, or may be provided via a first metal film composed of Al and Al alloy on said first metal film; moreover, it may be laminated on the amorphous oxide film with the following sequence; the second metal film, the first metal film, and the second metal film.

Amorphous oxide films include transparent conductive films and amorphous oxide semiconductor films.

Examples of the transparent conductive films are not particularly limited, and may include not only p-ITO, but also transparent conductive films comprising a-ITO, IZO, zinc oxide, and tin oxide, etc. The etching solution composition of the present invention may be particularly preferably used for α-ITO, IZO, zinc oxide, tin oxide, etc.

The amorphous oxide semiconductor films that can be used for the present invention comprise at least one of Ga, Zn and Sn.

In the following descriptions, for simplicity, an oxide comprising In, Ga and Zn (In—Ga—Zn—O) is represented by IGZO. Similarly, an oxide comprising In and Zn (In—Zn—O) is represented by IZO, and an oxide comprising In, Sn and Zn (In—Sn—Zn—O) is represented by ITZO.

In the amorphous oxide semiconductor films used in the present invention, one or more impurities selected from Al, Sb, Cd, Ge, P, As, N and Mg may be added to IZO, IGZO and ITZO. In such cases, however, the allowable content of the above impurities is 10 atomic percent (at %) or less, since they may adversely affect the properties of the semiconductor films.

In the present invention, the total amount of at least one of Ga, Zn and Sn, as well as In and oxygen (O) is preferably 90 at % or more, more preferably 95 at % or more, and most preferably 99 at % or more.

Ga atoms and Zn atoms in IGZO used in the present invention are contained at preferably 5 at % or more, and more preferably 10 at % or more. The percentage of Ga atoms and Zn atoms in IGZO is at the highest preferably less than 40 at %.

Zn atoms in IZO used in the present invention are contained at preferably 20 at % or more, and more preferably 30 at % or more, and they are preferably contained at less than 70 at %.

Alternatively, Sn atoms in ITZO used in the present invention are contained at preferably 2 at % or more, and more preferably 5 at % or more. The percentage of Sn atoms is at the highest preferably less than 20 at %, and more preferably less than 15 at %. In addition, Zn atoms are contained at preferably 20 at % or more, and more preferably 30 at % or more, and they are preferably contained at less than 70 at %.

Materials for the amorphous oxide semiconductor films used in the present invention are preferably amorphous oxide semiconductors with an electronic carrier concentration of less than 10¹⁸/cm³. In addition, in the present invention, said amorphous oxides may be those comprising microcrystalline regions such as IGZO, IZO and ITZO within said amorphous oxide films.

Specifically, the above amorphous oxide films are those composed of In—Ga—Zn—O, and their composition is represented by InGaO₃(ZnO)ₘ (m is a natural number from 2 to 6) assuming that they are crystalline. In addition, when the above amorphous oxide films are those composed of In—Zn—O, their composition is represented by In₂O₃(ZnO)ₘ (m is a natural number from 2 to 6) assuming that they are crystalline. In addition, when the above amorphous oxide films are those composed of In—Sn—Zn—O, their composition is represented by In₂GaO₃(ZnO)ₘ (m is a natural number from 2 to 6), Sn₂ZnO₃ and SnZn₂O₄, assuming that they are crystalline.

The etching solution of the present invention may be suitably used particularly for Al films or Al alloys. Examples of Al alloys include AlNd, AlNi, AlCr, AlFe, AlTi, AlCe, etc. Examples of Cu alloys include CuMo, CuZr, CuMn, CuAu, CuMg, CuAl, CuSi, CuNi, CuTi, CuCo, etc. Examples of Ag alloys include AgMo, AgZr, AgSi, AgGe, AgCu, AgSn, AgBi, AgPd, AgNd, AgPdCu, etc. Furthermore, the laminated film may comprise a second metal film such as Mo and Mo alloys (MoW, MoNb, MoAg, MoTi, MoZr, MoV, MoCr, etc.) and Ti and Ti alloys (TiW, TiMo TiN, etc.) in order to prevent oxidation of Al, or it may be a single film of the second metal film. The first metal film may be etched simultaneously with this second metal film.

The above metal film can be formed over the amorphous oxide semiconductor film. Specifically, excellent selective etching is enabled for two-layered structures of substrate/IZO/metal film, substrate/IGZO/metal film and substrate/ITZO/metal film. In particular, more excellent selective etching is enabled for substrate/IGZO/metal film and substrate/ITZO/metal film.

In order to increase the etch rate and to obtain good etching selectivity between oxide semiconductor and metal film, addition of an oxidizing agent such as hydrogen peroxide, potassium permanganate, ammonium persulfate and peroxoammonium disulfate is preferred. Etching of metal films such as Mo, Mo alloy, Cu, Cu alloy, Ag, Ag alloy, Mo, Mo alloy, Ti and Ti alloy can be facilitated by the addition of an oxidizing agent.

The etching solution composition of the present invention can be used in the etching step of laminated films upon manufacturing liquid crystal display panels of FFS and IPS modes, or semi-transmissive/semi-reflective liquid crystal display panels Specific examples of such laminated films include, as shown in FIG. 1, a laminated film consisting of a transparent conductive film, a metal-wiring film such as Al and Al alloy, and an oxidation-resistant film of Mo and MoW alloy, over a glass substrate, etc.

The etching solution composition of the present invention comprises an alkali. The alkali used in the present invention may be any substance that makes the etching solution composition alkaline, and may be both organic and inorganic alkali. Examples of organic alkali include tetramethylammonium hydroxide (TMAH), etc. Examples of inorganic alkali include ammonia, NaOH, KOH, NaHCO₃, etc. Of these, ammonia is particularly preferred. The etching solution composition of the present invention is mainly composed of the above alkali and a solvent. As the solvent, aqueous solvent is preferred, and water is particularly preferred.

The pH value of the etching solution composition is preferably 7-12, and more preferably 8-11. When the pH value is low, etching of Al does not proceed well, and when the pH value is high, the resist will peel off.

The concentration of an alkali in the etching solution composition is preferably 0.01-25 wt %, and more preferably 1-10 wt %. When the alkali concentration is less than 0.01 wt %, etching of Al does not proceed well, and when the alkali concentration exceeds 25 wt %, the resist may peel off in some cases. When the etching solution composition is ammonia water, the alkali concentration is preferably 0.01-25 wt %, more preferably 1-10 wt %, and furthermore preferably 1-7 wt %.

When used for a laminated film comprising an amorphous oxide semiconductor film, the alkali concentration of the etching solution composition is preferably 0.01-5 wt %, and more preferably 1-5 wt %. When the alkali concentration exceeds 5 wt %, selective etch of the metal film and amorphous oxide semiconductor film may become difficult in some cases.

When the etching solution composition is ammonia, the alkali concentration is preferably 0.01-5 wt %, and more preferably 1-4 wt %.

By adjusting the alkali concentration within the above concentration range of the present invention, the etching selectivity of IGZO vs. metal film, IZO vs. metal film, and ITZO vs. metal film falls within 10-100. When the value of etching selectivity is 10 or more, selective etching is mostly possible. In addition, even when the upper region of the partial amorphous oxide semiconductor film is etched, it does not greatly affect the semiconductor characteristic. In this case, the thickness of the amorphous oxide semiconductor film to be etched should be suppressed to less than 30% at the largest. More preferably, it should be less than 20%, and furthermore preferably less than 10%.

In the present invention, when semiconductor elements are manufactured using the above indium oxide semiconductor film such as IZO, IGZO and ITZO as a semiconductor active layer, the production yield can be increased. It is particularly effective to manufacture semiconductor elements on a large-area substrate.

In the etching step of the present invention, either negative resist or positive resist may be used. When a positive resist is used as an etching mask, since the etching solution composition comprising ammonia has a possibility of peeling off the positive resist, immersion etching for a long period of time is not preferred. Accordingly, in cases of using a solution with an ammonia concentration of 20 wt %, etching time is desirably 30 min. or less, and more desirably 15 min. or less.

In order to avoid the problem of peeling off of resists, it is also preferable to use negative resists with strong resistance to alkaline solution, such as photosensitive polyamide.

The etching solution composition of the present invention preferably comprises an oxidizing agent such as hydrogen peroxide, potassium permanganate, ammonium persulfate and peroxoammonium disulfate, in order to increase etch rate and to obtain good etching selectivity between amorphous oxide film and metal film. Hydrogen peroxide is particularly preferable as an oxidizing agent. Etching of metal films composed of Mo, Mo alloy, Cu, Cu alloy, Ag, Ag alloy, Ti, Ti alloy can be facilitated by the addition of an oxidizing agent.

The concentration of an oxidizing agent in the etching solution composition is preferably 0.01-20 wt %, and more preferably 1-10 wt %. When the concentration is less than 0.01 wt %, in some cases no effect of addition of hydrogen peroxide is observed, the etch rate of the metal film cannot be increased, and selective etching of amorphous oxide film cannot be achieved. When the concentration exceeds 20 wt %, the surface of the metal film may be oxidized and it may become non-conductive.

When the oxidizing agent is hydrogen peroxide, the concentration of the hydrogen peroxide in the etching solution composition is preferably 0.01-20 wt %, more preferably 1-10 wt %, and furthermore preferably 1-5 wt %.

The etching solution composition of the present invention selectively etches a metal film formed over an amorphous oxide film, said metal film composed of at least one selected from the group consisting of Al, Al alloy, Cu, Cu alloy, Ag and Ag alloy. To use the etching solution composition for etching step of liquid crystal display panels and liquid crystal display devices, it is preferable not to damage the amorphous oxide film formed beneath the metal film. To achieve this, the etching selectivity (etch rate of the metal film/etch rate of the amorphous oxide film) should be preferably 2 or more, more preferably 5 or more, and particularly preferably 10 or more.

The etching solution composition of the present invention may comprise other components such as chelating agents and surfactants, if necessary, within the range that does not deteriorate the effects of the present invention. Examples of the chelating agents include ethylenediaminetetraacetic acid (EDTA) and diethylenetriaminepentaacetic acid (DTPA), as well as salts thereof. These chelating agents have an effect to suppress degradation of hydrogen peroxide. In addition, as the surfactant, nonionic surfactant or anionic surfactant is preferred.

The temperature of the etching solution composition in an etching step of the present invention can be at room temperature (approximately 20° C.). Meanwhile, since thermal conductivity of amorphous semiconductor films such as IZO, IGZO and ITZO varies Significantly with temperature, it is preferable not to change the temperature during the etching step. In addition, when the temperature of the etching solution composition is high, the concentration of the composition changes due to the evaporation of said ammonia and water; accordingly, the temperature during etching steps is preferably maintained at 60° C. or less, and more preferably 50° C. or less.

Hereinafter, the structure of a thin-film transistor in which the etching step of the present invention can be adopted is described.

FIG. 2 shows a schematic cross-sectional diagram of a bottom-gate thin-film transistor (TFT). As shown in FIG. 2, “1” represents a substrate such as glass, quartz grass, or silicon on the surface of which an insulation layer has been formed. “4” and “5” represent a source electrode and a drain electrode, respectively, consisting of a metal film composed of at least one selected from the group consisting of Al, Al alloy, Cu, Cu alloy, Ag, Ag alloy, Mo and Ti. “6” represents a semiconductor layer (called active layer or channel layer) composed of an amorphous oxide semiconductor film such as IGZO, ITZO and IZO. In addition, “3” represents a gate insulating layer, “2” represents a gate electrode consisting of a metal film composed of at least one selected from the group consisting of Al, Al alloy, Cu, Cu alloy, Ag, Ag alloy, Mo and Ti. L represents channel length. The etching step of the present invention can be suitably used for etching drain electrode and source electrode consisting of a metal film composed of at least one selected from the group consisting of Al, Al alloy, Cu, Cu alloy, Ag, Ag alloy, Mo and Ti.

### (Manufacturing Process of Thin-Film Transistor)

Hereinafter, a manufacturing process of bottom-gate TFTs is described with reference to FIG. 3.

As shown in FIG. 3(a), as the substrate 1, for example, a glass with a 500 μm thickness (Corning 1737, glass transition temperature of 640° C.) is used. Then, for example, a multilayered film of Al (film thickness 250 nm)/Mo (film thickness 50 nm) is formed on the substrate surface by sputtering. Next, a gate electrode 2 of Al/Mo metal film is formed by patterning by etching with a mixed acid of phosphoric acid/acetic acid/nitric acid.

As shown in FIG. 3(b), SiO₂ film is formed on the gate electrode 2 by sputtering, a gate insulating layer 3 is formed with a film thickness of 300 nm, then an IGZO film is formed with a film thickness of 50 nm by sputtering using IGZO oxide target. As the above IGZO film, those with an electronic carrier concentration less than 10¹⁸/cm³ are preferably used. In addition, a heat treatment in air at 200-300° C. for 10-100 min. is preferably carried out.

Subsequently, a resist pattern is formed and etched with an oxalic acid solution (2 wt %) to form an island of the oxide semiconductor.

In FIG. 3(c), a laminated film of Mo/Al/Mo with respective thickness of 50 nm/200 nm/50 nm is formed, and a resist pattern is formed, then the Mo/Al/Mo laminated film is etched with an alkaline etching solution composition comprising an oxidizing agent, i.e., specifically, an aqueous solution of ammonia (3 wt %) and hydrogen peroxide (5 wt %), to form source-drain electrodes composed of the Mo/Al/Mo laminated film. Upon formation, when an aqueous solution of ammonia (3 wt % concentration) and hydrogen peroxide (5 wt % concentration) at room temperature is used, the etching selectivity of IGZO vs. Mo/Al/Mo laminated film is 10:1. Namely, since the etch rate of the Mo/Al/Mo laminated film is sufficiently large and the etch rate of the IGZO is sufficiently small, Mo/Al/Mo is selectively etched off and IGZO is hardly etched.

As the metal film, a metal film composed of at least on selected from the group consisting of Cu, Cu alloy, Ag, Ag alloy, Mo and Ti is preferably used.

Instead of silicon oxide film (SiO₂), as a gate insulating film 3, it is possible to use dielectric materials such as nitride-oxide-silicon film (SiNOₓ), hafnium oxide film (HfO₂), oxide-hafnium-aluminum film (HfAlOₓ), nitride-oxide-hafnium-silicon film (HfSiONₓ) and yttrium oxide film (Y₂O₃). These dielectric materials have high dielectric constant, and are suitably used for gate insulating layers.

Thus, a thin-film transistor (TFT) composed of an oxide wherein the active layer comprises indium can be manufactured.

### BRIEF DESCRIPTION OF DRAWINGS

FIG. 1 is a cross sectional diagram showing one example of liquid crystal display panels comprising a laminated film having a metal film and a transparent conductive film.

FIG. 2 is a schematic cross-sectional diagram of a bottom-gate thin-film transistor (TFT).

FIG. 3 is a diagram showing a manufacturing process of bottom-gate TFTs.

FIG. 4 is a graph showing changes in resistance value against immersion time, when a transparent conductive layer is etched using the etching solution composition of the present invention.

FIG. 5 is a schematic cross-sectional diagram of the bottom-gate TFT, when etched using the etching solution composition of the present invention.

FIG. 6 is a graph showing properties of the bottom-gate TFT.

FIG. 7 is a schematic cross-sectional diagram of the bottom-gate TFT when etched using an etching solution composition of mixed acid of phosphoric acid/acetic acid/nitric acid.

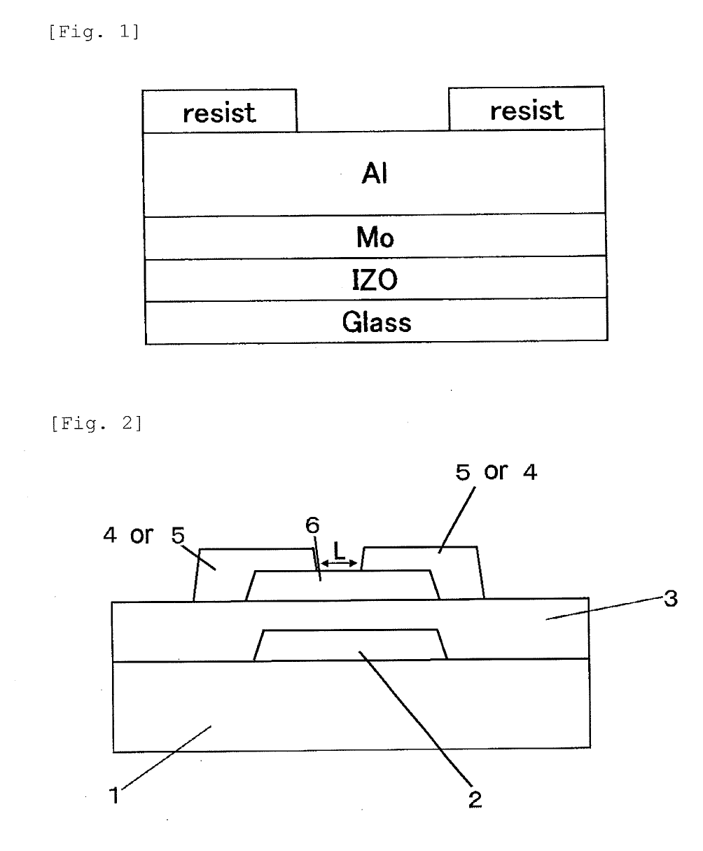

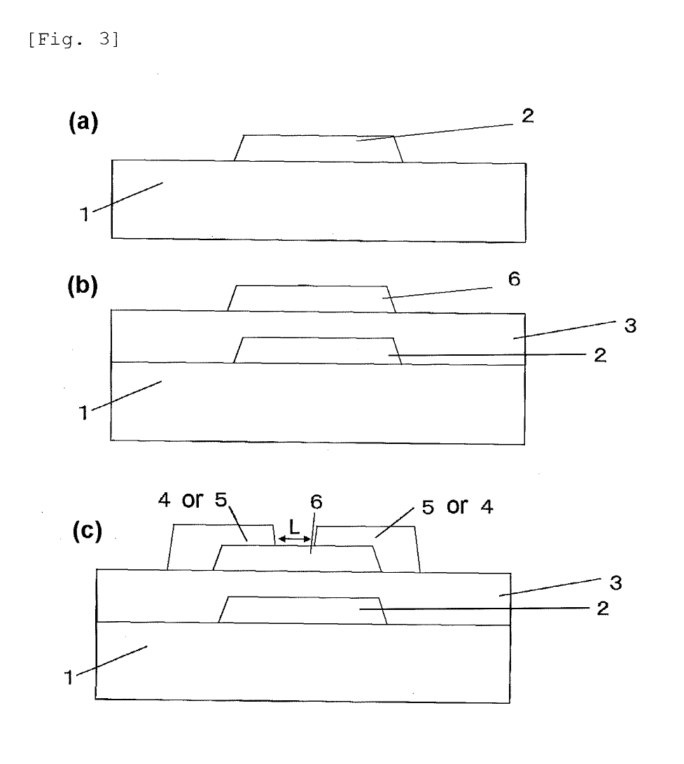

### DESCRIPTION OF SYMBOLS

1. Glass
2. Gate electrode
3. Gate insulating layer
4. Metal film (source electrode)
5. Metal film (drain electrode)
6. Semiconductor layer
7. Hard doped Si substrate.

### EXAMPLES

The present invention is explained in detail using the following examples; however, the present invention is not limited to these examples.

### Example 1

In a 200-ml beaker, 48.3 g of ammonia water (29 wt %), 9.7 g of hydrogen peroxide solution (31 wt %), and 142 g of water were added to prepare an etching solution composition composed of 200 g of aqueous solution comprising 7 wt % of ammonia and 1.5 wt % of hydrogen peroxide.

### (Evaluation Experiment 1)

A substrate consisting of patterned positive resist/Al (2000 Å)/Mo (500 Å)/IZO (500 Å)/glass was immersed in the above-prepared alkaline etching solution composition, and just-etching time of the Al/Mo laminated film was visually measured to obtain etch rate of the Al/Mo laminated film. Table 1 shows the results.

### Examples 2-15

Etching solution compositions were prepared in accordance with the procedure of Example 1, except that the concentrations of ammonia and hydrogen peroxide were changed to those listed in Table 1. The evaluation experiment 1 was performed as in Example 1 for the prepared etching solution compositions, and etch rates of Al/Mo laminated films were obtained. Table 1 shows the results.

TABLE 1

| | | Hydrogen | | Liquid | Etch |
|---|---|---|---|---|---|
| Etching | Ammonia | peroxide | Water | temperature | rate |
| solution | (wt %) | (wt %) | (wt %) | (° C.) | (Å/min) |
| Example 1 | 7 | 1.5 | 91.5 | 40 | 1667 |
| Example 2 | 7 | 20 | 73 | 40 | 500 |
| Example 3 | 7 | 15 | 78 | 40 | 739 |
| Example 4 | 7 | 10 | 83 | 40 | 987 |
| Example 5 | 7 | 5 | 88 | 40 | 1974 |
| Example 6 | 7 | 1 | 92 | 40 | 2885 |
| Example 7 | 7 | 0.5 | 92.5 | 40 | 2055 |
| Example 8 | 7 | 0.1 | 92.9 | 40 | 1705 |
| Example 9 | 25 | 1.5 | 73.5 | 40 | 1364 |
| Example 10 | 15 | 1.5 | 83.5 | 40 | 2055 |
| Example 11 | 5 | 1.5 | 93.5 | 40 | 2500 |
| Example 12 | 3 | 1.5 | 95.5 | 40 | 2308 |
| Example 13 | 1 | 1.5 | 97.5 | 40 | 1563 |
| Example 14 | 3 | 3 | 94 | 40 | 1765 |
| Example 15 | 14 | 15 | 71 | 40 | 670 |

### Comparative Examples 1-4

Etching solution compositions were prepared in accordance with the procedure of Example 1, except that phosphoric acid, nitric acid and acetic acid were used instead of ammonia and hydrogen peroxide, and concentrations were changed to those listed in Table 2. The evaluation experiment 1 was performed as in Example 1 for the prepared etching solution compositions, and etch rates of Al/Mo laminated films were obtained. Table 2 shows the results.

TABLE 2

| | | Nitric | | | Liquid | |
|---|---|---|---|---|---|---|
| | Phosphoric | acid | Acetic | | temper- | Etch |
| Etching | acid | (wt | acid | Water | ature | rate |
| solution | (wt %) | %) | (wt %) | (wt %) | (° C.) | (Å/min) |
| Comparative | 73.3 | 2.7 | 6.7 | 17.3 | 30 | 1667 |
| example 1 | | | | | | |
| Comparative | 50 | 5 | 30 | 15 | 30 | 882 |
| example 2 | | | | | | |
| Comparative | 50 | 0.5 | 40 | 9.5 | 30 | 714 |
| example 3 | | | | | | |
| Comparative | 30 | 10 | 40 | 20 | 30 | 556 |
| example 4 | | | | | | |

### (Evaluation Experiment 2)

Using the etching solution compositions of Examples 1, 14 and 15, and of Comparative examples 1-4, an IZO film was etched, and the etch rate and etching selectivity were measured by measuring the film thickness. Table 3 shows the results.

TABLE 3

| Etching | Al/Mo etch rate | IZO etch rate | Selectivity of |
|---|---|---|---|
| solution | (Å/min) | (Å/min) | Al/MO and IZO |
| Example 1 | 1667 | 21 | 79.3:1 |
| Example 14 | 1765 | 36 | 49:1 |
| Example 15 | 670 | 59 | 11.3:1 |
| Comparative | 1667 | 880 | 1.9:1 |
| example 1 | | | |
| Comparative | 882 | 1050 | 0.84:1 |
| example 2 | | | |
| Comparative | 714 | 690 | 1:1 |
| example 3 | | | |
| Comparative | 556 | 1030 | 0.5:1 |
| example 4 | | | |

### Example 16

The etching solution composition shown in Table 4 was prepared in accordance with the procedure of Example 1, except that ammonia and water were added to make the ammonia content of 7 wt %.

TABLE 4

| | | Hydrogen | | Liquid |
|---|---|---|---|---|
| Etching | Ammonia | peroxide | | temperature |
| solution | (wt %) | (wt %) | Water (wt %) | (° C.) |
| Example 16 | 7 | 0 | 93 | 40 |

### (Evaluation Experiment 3)

The etch rates of the etching solution compositions of Example 1 and Example 16 shown in Table 4 for the films of Al, Cu, IZO, p-ITO or α-ITO were measured. Table 5 shows the results, and Table 6 shows the etching selectivity.

TABLE 5

| | Al etch | Cu etch | IZO etch | p-ITO | α-ITO |
|---|---|---|---|---|---|
| Etching | rate | rate | rate | etch rate | etch rate |
| solution | (Å/min) | (Å/min) | (Å/min) | (Å/min) | (Å/min) |
| Example 1 | 700 | 54780 | 21 | 68 | 111 |
| Example 16 | 328 | — | 66 | 91 | 148 |

TABLE 6

| | Selectivity | Selectivity | Selectivity | Selectivity | Selectivity | Selectivity |
|---|---|---|---|---|---|---|
| Etching | between | between | between | between | between | between |
| solution | Al/IZO | Al/p-ITO | Al/α-ITO | Cu/IZO | Cu/p-ITO | Cu/α-ITO |
| Example 1 | 33.3:1 | 10.3:1 | 6.3:1 | 2609:1 | 5318:1 | 494.1:1 |
| Example | 5.0:1 | 3.6:1 | 2.2:1 | — | — | — |
| 16 | | | | | | |

As described above, the selectivities between Al/Mo and IZO by the conventional acidic etching solutions were 0.5-1.9:1, and most of the IZO films disappeared by approximately 30 s of etching. On the other hand, etching of the transparent conductive film could be suppressed by the use of the inventive alkaline etching solution composition, and the etching selectivity of 2 or larger could be obtained. Furthermore, selective etching between Al and α-ITO/p-ITO, etc. is also possible.

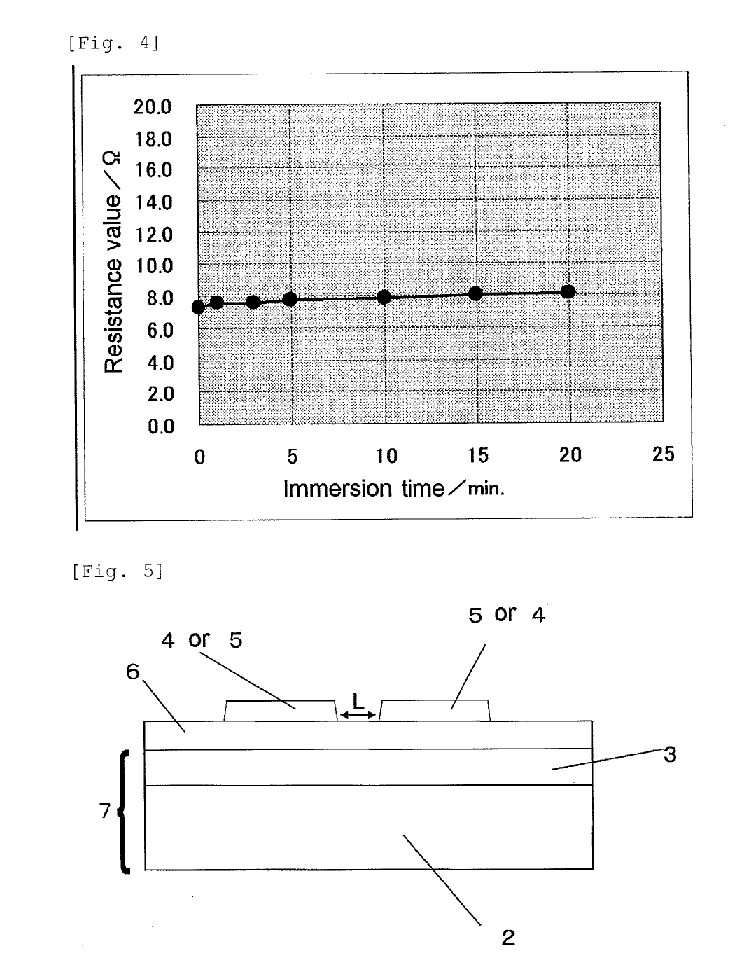

FIG. 4 shows changes in resistance value upon immersing into the etching solution composition of Example 1.

As described above, the inventive alkaline etching solution composition elicits almost no change in resistance value, so that the composition is suitable for not only liquid crystal devices, but also as transparent electrodes for PDPs, EL luminescent display devices, touch panels, solar cells, etc.

### Example 17

In a 200-ml beaker, 34.5 g of ammonia water (29 wt %), 9.7 g of hydrogen peroxide solution (31 wt %), and 155.8 g of water were added to prepare an etching solution composition composed of 200 g of aqueous solution comprising 5 wt % of ammonia and 1.5 wt % of hydrogen peroxide.

### (Evaluation Experiment 4)

A substrate consisting of patterned positive resist/Al (200 nm)/Mo (50 nm)/oxide semiconductor (In/(In+Ga+Zn)=0.40, Ga/(In+Ga+Zn)=0.15, Zn/(In+Ga+Zn)=0.45 (50 nm)/hard doped silicon substrate having a thermal oxide film (300 nm) was immersed in the above-prepared alkaline etching solution composition, and etching time of the Al/Mo laminated film was visually measured to obtain etch rate of the Al/Mo laminated film. Table 7 shows the results.

### Examples 18-26

Etching solution compositions were prepared in accordance with the procedure of Example 17, except that the concentrations of ammonia and hydrogen peroxide were changed to those listed in Table 7. The evaluation experiment was performed for the prepared etching solution compositions simultaneously with Example 17, and etch rates of Al/Mo laminated films were obtained. Table 7 shows the results.

TABLE 7

| | | | Liquid | |
|---|---|---|---|---|
| Etching | Ammonia | Hydrogen | temperature | Etch rate |
| solution | (wt %) | peroxide (wt %) | (° C.) | (nm/min) |
| Example 17 | 5 | 1.5 | 40 | 167 |
| Example 18 | 4 | 10.0 | 40 | 99 |
| Example 19 | 4 | 5.0 | 40 | 197 |
| Example 20 | 4 | 1.0 | 40 | 289 |
| Example 21 | 4 | 0.5 | 40 | 206 |
| Example 22 | 4 | 0.1 | 40 | 108 |
| Example 23 | 4 | 1.5 | 40 | 250 |
| Example 24 | 3 | 1.5 | 40 | 231 |
| Example 25 | 1 | 1.5 | 40 | 156 |
| Example 26 | 3 | 3.0 | 40 | 177 |

### (Evaluation Experiment 5)

Using the etching solution compositions of Examples 24-26, an IGZO film (In/(In+Ga+Zn)=0.40, Ga/(In+Ga+Zn)=0.15, Zn/(In+Ga+Zn)=0.45) was etched and the etch rate and etching selectivity were measured by measuring film thickness. Table 8 shows the results.

TABLE 8

| | | Etch rate of | Etch rate of | Selectivity |
|---|---|---|---|---|
| | Etching | Al/Mo film | IGZO film | of Al/MO and |
| | solution | (nm/min) | (nm/min) | IZO |
| Example 27 | Example | 231 | 2.5 | 92:1 |
| | 24 | | | |
| Example 28 | Example | 177 | 4.0 | 44:1 |
| | 25 | | | |
| Example 29 | Example | 67 | 6.5 | 10:0 |
| | 26 | | | |

### (Evaluation Experiment 6)

Using the etching solution compositions of Examples 24-26, an ITZO film (In/(In+Sn+Zn)=0.45, Sn/(In+Sn+Zn)=0.10, Zn/(In+Sn+Zn)=0.45) was etched and the etch rate and etching selectivity were measured by measuring film thickness. Table 9 shows the results.

TABLE 9

| | | Etch rate of | Etch rate of | Selectivity |
|---|---|---|---|---|
| | Etching | Al/Mo film | ITZO film | of Al/MO and |
| | solution | (nm/min) | (nm/min) | IZO |
| Example 30 | Example | 231 | 0.2 | 1155:1 |
| | 24 | | | |
| Example 31 | Example | 177 | 0.4 | 442:1 |
| | 25 | | | |
| Example 32 | Example | 67 | 0.5 | 134:0 |
| | 26 | | | |

### (Evaluation Experiment 7)

Using the etching solution compositions of Examples 24-26, an IZO film (In/(In+Zn)=0.65, Zn/(In+Zn)=0.35) was etched and the etch rate and etching selectivity were measured by measuring film thickness. Table 10 shows the results.

TABLE 10

| | | Etch rate of | Etch rate of | Selectivity |
|---|---|---|---|---|
| | Etching | Al/Mo film | IZO film | of Al/MO and |
| | solution | (nm/min) | (nm/min) | IZO |
| Example 33 | Example | 231 | 2.3 | 100:1 |
| | 24 | | | |
| Example 34 | Example | 177 | 3.6 | 49:1 |
| | 25 | | | |
| Example 35 | Example | 67 | 5.4 | 12:0 |
| | 26 | | | |

### Example 36

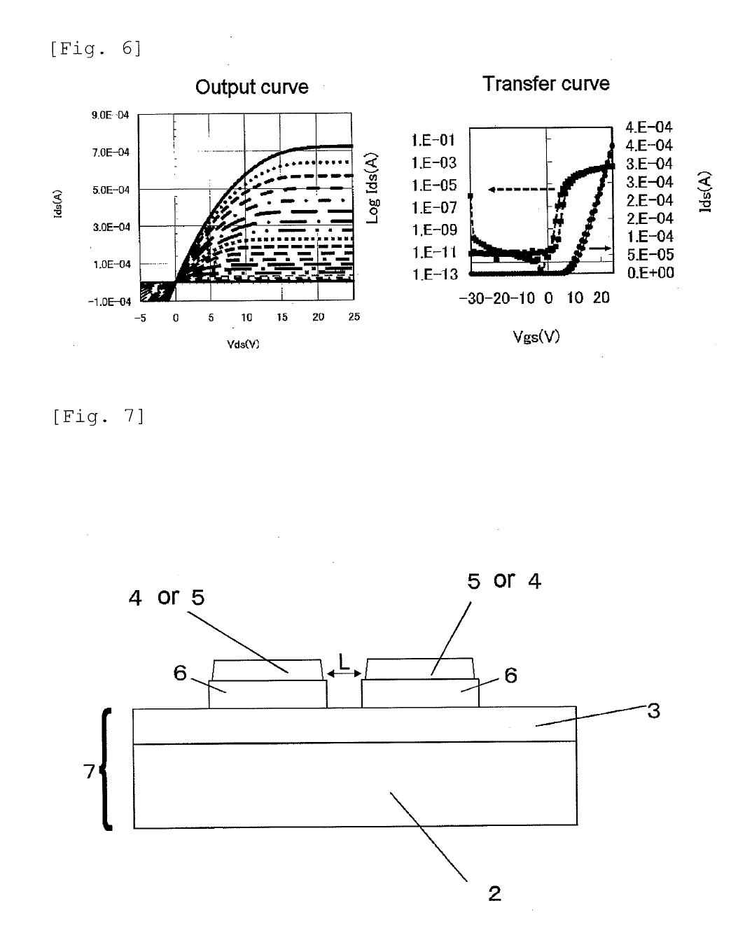

On a substrate consisting of a hard doped silicon substrate having a thermal oxide film (300 nm), an ITZO film (In/(In+Sn+Zn)=0.45, Sn/(In+Sn+Zn)=0.10, Zn/(In+Sn+Zn)=0.45) was formed with a thickness of 50 nm by sputtering, then after film formation, the film was subjected to heat treatment in air at 300° C. for 1 hr. A Mo/Al film was formed on the above substrate with a respective thickness of 50 nm/200 nm, on which a resist was coated, pre-baked at 80° C. and exposed to light through the mask to form a shape of source-drain electrodes; which was developed with TMAH, post-baked at 130° C., and formed into the source-drain electrodes using the etching solution composition of Example 24 (FIG. 5). Then a thin-film transistor element with a channel length of 200 μm and a channel width of 500 μm was produced, and its semiconductor properties were evaluated using a semiconductor parameter analyzer 4200-SCS from Keithley Instruments Inc. Results were as follows: On/Off value=10⁹, field-effect mobility=25 cm²/V·sec, threshold voltage (Vth)=7 V, and S value=0.8. These results demonstrated that the resulting element can sufficiently function as a thin-film transistor (FIG. 6).

The crystallinity of the above-obtained ITZO film (In/(In+Sn+Zn)=0.45, Sn/(In+Sn+Zn)=0.10, Zn/(In+Sn+Zn)=0.45) observed by X-ray diffraction showed no peaks, demonstrating that it is non-crystalline. In addition, its carrier density was estimated by Hall measurement (RESI TEST 8300, Tokyo Technica Inc.), and was found to be 2×10¹⁶/cm³.

### Comparative Example 5

On a substrate composed of a hard doped silicon substrate with heat oxide film (300 nm), an IGZO film (In/(In+Ga+Zn)=0.40, Ga/(In+Ga+Zn)=0.15, Zn/(In+Ga+Zn)=0.45) was formed with a thickness of 50 nm by sputtering, then after film formation, the film was subjected to heat treatment in air at 300° C. for 1 hr. A Mo/Al film was formed on the above substrate with a respective thickness of 50 nm/200 nm, on which a resist was coated, pre-baked at 80° C. and exposed to light through the mask to form a shape of source-drain electrodes; which was developed with TMAH, post-baked at 130° C., and formed into the source-drain electrodes using the etching solution composition of mixed acid of phosphoric acid/acetic acid/nitric acid. Then, the formation of a thin-film transistor element with a channel length of 200 μm and a channel width of 500 μm was attempted; however, the entire IGZO film of the channel part was etched and the formation of the thin-film transistor was unsuccessful. See FIG. 7.

### INDUSTRIAL APPLICABILITY

The etching solution composition of the present invention can be used for selective etch of a laminated film consisting of a metal film composed of Al, Al alloy, etc. and various types of amorphous oxide film, wherein the composition can selectively etch the metal film over the amorphous oxide film. Using the inventive composition, a high selectivity can be obtained even for amorphous transparent conductive films, of which selective etching has been conventionally impossible, so that the composition can be used for manufacturing liquid crystal display panels as well as semi-transparent/semi-reflecting liquid crystal panels with FFS and IPS modes. In addition, since the inventive etching solution composition elicits almost no change in resistance value, it can be used for transparent electrodes in PDPs, EL luminescent display devices, touch panels, and solar cells in addition to liquid crystal devices.

1. An etching solution composition for selectively etching a metal film from a laminated film comprising an amorphous oxide film and said metal film that is composed of at least one selected from the group consisting of Al, Al alloy, Cu, Cu alloy, Ag and Ag alloy, wherein the composition comprises an aqueous solution containing an alkali.

2. The etching solution composition according to claim 1, wherein the laminated film further comprises a metal film composed of at least one selected from the group consisting of Mo, Mo alloy, Ti and Ti alloy, and said metal film is simultaneously etched.

3. The etching solution composition according to claim 1, wherein the alkali is ammonia.

4. The etching solution composition according to claim 1, further comprising an oxidizing agent.

5. The etching solution composition according to claim 4, wherein the oxidizing agent is hydrogen peroxide.

6. The etching solution composition according to claim 1, wherein the amorphous oxide film is a transparent conductive film or an amorphous oxide semiconductor film, said transparent conductive film being a transparent conductive film comprising α-ITO, IZO, zinc oxide or tin oxide, and said amorphous oxide semiconductor film being an amorphous oxide semiconductor film comprising at least one of gallium, zinc and tin, and indium.

7. The etching solution composition according to claim 6, wherein the concentration of ammonia in the etching solution composition is 0.01-25% by weight.

8. The etching solution composition according to claim 6, wherein the concentration of hydrogen peroxide in the etching solution composition is 0.01-20% by weight.

9. The etching solution composition according to claim 6, wherein the amorphous oxide film is an amorphous oxide semiconductor film comprising at least one of gallium, zinc and tin, and indium, and the concentration of ammonia in the etching solution composition is 0.01-5% by weight.

10. The etching solution composition according to claim 6, wherein the amorphous oxide film is an amorphous oxide semiconductor film comprising at least one of gallium, zinc and tin, and indium, and the concentration of hydrogen peroxide in the etching solution composition is 0.01-10% by weight.

11. The etching solution composition according to claim 1, which is used for manufacturing a liquid crystal display panel.

12. The etching solution composition according to claim 1, which is used for manufacturing a liquid crystal display panel of FFS or IPS mode, or a semi-transmissive/semi-reflective liquid crystal display panel.

13. A laminated film comprising an amorphous oxide film and a metal film composed of at least one selected from the group consisting of Al, Al alloy, Cu, Cu alloy, Ag and Ag alloy, wherein said metal film is selectively etched using the etching solution composition according to claim 1.

14. A liquid crystal display panel having the laminated film according to claim 13.

15. A liquid crystal display device having the liquid crystal display panel according to claim 14.

16. An etching method for a laminated film comprising an amorphous oxide film and a metal film composed of at least one selected from the group consisting of Al, Al alloy, Cu, Cu alloy, Ag and Ag alloy, characterized in that said metal film is selectively etched using the etching solution composition according to claim 1.

17. The etching method according to claim 16, wherein the laminated film further comprises a metal film composed of at least one selected from the group consisting of Mo, Mo alloy, Ti and Ti alloy, and said metal film is simultaneously etched.

18. A patterning method of a metal film comprising at least one layer selected from the group consisting of Al, Al alloy, Cu, Cu alloy, Ag and Ag alloy disposed on an amorphous oxide film, characterized in that the method comprises a step of forming the amorphous oxide film, a step of forming the metal film over the amorphous oxide film, and an etching step of selectively etching the metal film on the amorphous oxide film using the etching solution composition according to claim 1.

19. A process for manufacturing a liquid crystal display panel, comprising an etching step using the etching solution composition according to claim 1.

20. A process for manufacturing a thin-film transistor comprising a step of forming source and drain electrodes, a gate electrode, a gate insulating layer and a semiconductor layer, characterized in that said step of forming the semiconductor layer comprises a step of forming an amorphous oxide film, a step of forming a metal film that comprises at least one selected from the group consisting of Al, Al alloy, Cu, Cu alloy, Ag and Ag alloy over the amorphous oxide film, and an etching step of selectively etching the metal film on the amorphous oxide film using the etching solution composition according to claim 1.
